(19) United States
(12) Patent Application Publication
(10) Pub. No.: US 2002/0013054 A1
(43) Pub. Date: Jan. 31, 2002

(54) Single crystal silicon micro-actuator/mirror and method therefor

(76) Inventors: Kenneth R. Farmer, II, Dunellen, NJ (US); Richard A. Brown, North Fitzroy (AU); Vladimir Anatolyevich Aksyuk, Piscataway, NJ (US); David John Bishop, Summit, NJ (US); James Albert Walker, Howell, NJ (US)

Correspondence Address: Richard C. Woodbridge, Esq., Woodbridge & Associates, P.C., P.O. Box 592, Princeton, NJ, 08542-0592, US

(21) Appl. No.: 09/854,288

(22) Filed: May 11, 2001

Related U.S. Application Data
(60) Provisional application No. 60/203,545, filed on May 12, 2000.

(51) Int. Cl. H01L 21/302; H01L 21/461

(52) U.S. Cl. 438/689

(57) ABSTRACT

A simple method for making large, uniformly flat electrostatically actuated micro-mirrors for use as variable attenuators and switches in optical networking systems is disclosed. The devices are fabricated by fusion bonding ultra-thin, single crystal silicon wafers to micromachined silicon substrates, forming robust, non-deforming reflective surfaces which are simpler to fabricate than similar devices fabricated by conventional chemical vapor deposition of polycrystalline silicon, which require careful engineering to avoid stress-induced deformation.

This Application claims priority from the U.S. patent application Ser. No. 60/203,545, filed May 12, 2000, entitled SINGLE CRYSTAL SILICON MICRO-ACTUATOR/MIRROR AND METHOD THEREFOR, citing as coinventors Kenneth R. Farmer, Richard A. Brown, Vladmir A. Aksyuk, David J. Bishop and James A. Walker, the entire contents and substance of which is hereby incorporated in total by reference.

### BACKGROUND OF THE INVENTION

1. Field of the Invention

This invention relates to a method for fabricating a single crystal silicon micro-actuator/mirror.

2. Description of Related Art

The shift of the Internet from the government and university realm into the public, commercial sphere has created unprecedented levels of growth in the demand for network services. Much of the existing network infrastructure is unable to meet these demands. Typically, these systems multiple 45 Megabit per second (Mb/s) electrical signals to higher bit rates and transmit them on a single optical fiber. The recent development of dense wavelength division multiplexing (DWDM) systems has allowed these systems to expand by transmitting more than sixteen wavelength channels of data on a single fiber, at 2.5 gigabit per second Gb/s per channel. Currently, the latest commercially available DWDM systems allow up to 160 channels at 10 Gb/s per channel but development systems using standard single mode optical fibers have demonstrated 3.2 Terabit per second Tb/s with 80 channels at 40 Gb/s per channel. However, this extraordinary expansion of network capacity must be matched by a commensurate expansion of network management infrastructure.

Existing optical networks require frequent conversion of the optical signals to the electrical domain and back again at repeaters and add/drop multiplexers with associated high cost and loss of flexibility. This has led to the vision of an all-optical ‘photonic’ network architecture, where signal amplification and switching functions are all performed at the optical layer. When considered together with the exponential growth of network bandwidth, the need to develop high performance, low cost active optical elements is obviously desirable. Such elements include tunable lasers and filters, optical attenuators and switches. Currently all of these elements are built with silicon micro-machining (MEMS) techniques. MEMS based free space optical elements have the advantage of lower signal degradation than waveguide technology, reducing the requirements for optical amplification, and, therefore, lowering the system cost.

The micro-machined versions of the optical elements listed above all have at their core the common element of a movable reflective membrane. In order to achieve low insertion loss, that is, low signal attenuation, with typical beam divergences, and system geometries, the reflective surfaces must be rather large, on the order of 700×700 μm². However, large flat mirrors cannot be easily fabricated using conventional silicon deposition and micro-machining technology because the mirror surface, which is composed of gold (Au) on polycrystalline silicon (Si) for wavelength independent reflectivity near 1.5 μm, constitutes a bimorph structure which is generally highly non-planar. In particular, the mirror will deform with variations in temperature, resulting in poor performance. While it is possible to work around these problems by careful design and stress engineering, a simpler solution is to make the device insensitive to stress by using an extremely thick silicon layer. This also allows the development of highly reflective or wavelength selective devices based on dielectric stacks, where the stresses would be more difficult to compensate.

Aksyuk et al. describes a micro-machined optical switch in U.S. Pat. No. 5,923,798. Farmer et al. describes a technique for bonding a thin wafer layer to a substrate in U.S. Pat. No. 5,843,832.

### BRIEF SUMMARY OF THE INVENTION

The invention relates to a method for fabricating a micro-machined, electrostatically-actuated optical attenuator/switch.

The device contains a large area electrostatically actuated micro-mirror for use as variable attenuator or switch in optical networking systems. One embodiment has a reflective surface ranging from 400 to 700 micrometers square and from 2 to 200 microns thick with two torsional springs mounted on adjacent corners. The torsional springs may contain from 1 to 3 elements depending on the application and the desired spring constant. In alternate embodiments the reflective surface may be in the shape of a circle. The reflective element is a front surface mirror coated with a thin reflective coating to bounce the incoming light beam back to a receiver. A bias voltage is applied across the reflective coating on the reflector and the silicon substrate. The reflective surface deflects toward the substrate when the bias voltage is applied. The angle at which the reflective surface deflects the incoming beam is determined by the bias voltage value. A deflection angle of up to 1 degree has been achieved with the device. The thickness of the reflective element is such that it remains flat over the desired range of deflection angles.

The devices are fabricated by fusion bonding ultra-thin, defined as less than 200 microns, single crystal silicon wafers to a micro-machined silicon substrate. This forms robust, non-deforming reflective surfaces which are simpler to fabricate than similar devices fabricated by conventional chemical vapor deposition of polycrystalline silicon, which require careful engineering to avoid stress-induced deformation. Deep Reactive Ion Etching (DRIE) is used to form the torsional spring structures and the outline of the reflective surface. Finally, a chromium layer is deposited on the silicon reflective element and a layer of gold is used as the reflecting surface.

The invention may be more fully understood by reference to the following drawings.

### BRIEF DESCRIPTION OF THE DRAWINGS

FIGS. 1a-1d shows the steps of the method of fabrication for a preferred of this invention.

FIG. 2a illustrates a SEM micrograph of the micromirror structure.

FIG. 2b illustrates a close-up view of springs of FIG. 2a.

FIG. 3a illustrates a profilometer image of the micromirror of FIG. 2a.

FIG. 3b illustrates a typical depth profile.

FIG. 3c illustrates mirror deflection angle as a function of applied voltage.

### DETAILED DESCRIPTION OF THE INVENTION

During the course of this description like numbers will be used to identify like elements according to the different figures which illustrate the invention.

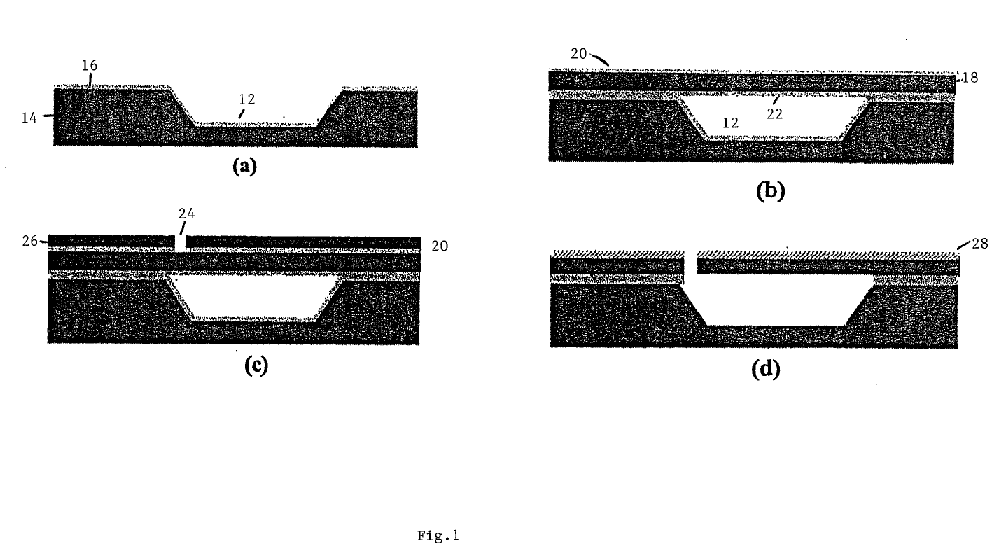

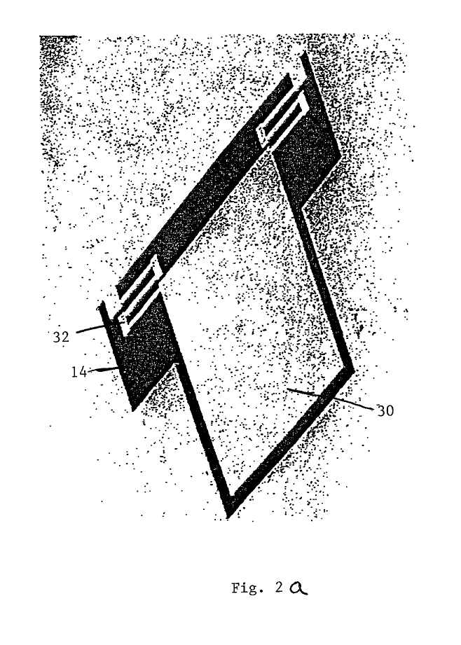

FIGS. 1a-1d depict the sequence of method steps for the fabrication of a preferred embodiment of the invention. Bulk anisotropic etching with potassium hydroxide is used to produce a plurality of cavities 12 in 4-inch standard low resistivity silicon substrate wafers 14 of standard thickness of approximately 500 μm by techniques known in the art. The substrate wafers 14 are then oxidized by a standard thermal process such as treatment with oxygen and water vapor at 1050-1100° C. for one hour to form an insulating layer of silicon dioxide 16 of approximately 1 μ. FIG. 1a illustrates one such cavity. Ultra-thin low resistivity silicon wafers 18 having a thickness of 200 μm or less, preferably about 50 μm, are oxidized using standard techniques to form a top and bottom silicon dioxide layer, 20 and 22 respectively, and then fusion bonded to the substrate wafers 14 in a vacuum chamber, forming sealed cavities 12, as depicted in FIG. 1b. The bonding process can be accomplished by standard techniques such as with an EV 501 universal bonding tool available from EVI. The edges of the silicon substrate wafers and the ultra-thin wafers are initially kept apart by means of spacers, so that initial contact between the wafers is made at their centers. Removal of the spacers allows contact to proceed from the centers to the edges. After applying a moderate amount of pressure to ensure complete contact, bonding is completed by heating the combined wafers at 1050-1100° C. for 1-2 hr.

A mirror surface shape and springs are then patterned 24 in the top layer using photoresist 26 as depicted in FIG. 1c. Treatment of the top silicon dioxide layer 20 of the ultra-thin wafer 18 with wet hydrogen fluoride etches through the silicon dioxide layer. Removal of the silicon layer 18 of the ultra-thin wafer is then accomplished by inductively coupled plasma Deep Reactive Ion Etching (DRIE). Removal of the silicon dioxide layers 20, 22 and 24 from the ultra-thin wafer, and the silicon dioxide layer 16 on the walls of cavity 14 is accomplished by treatment with wet hydrogen fluoride. Vapor deposition on the mirrors of a layer of chromium metal approximately 50 Å thick, followed by vapor deposition of a layer of gold approximately 200 Å thick, shown in FIG. 1d, creates reflective mirror surfaces 28.

In one embodiment of the present invention, approximately 1000 mirrors are fabricated on 4-inch standard low resistivity silicon substrate wafers 14. The wafers (Put in #) can then be diced into single mirrors or arrays of mirrors and mounted for use.

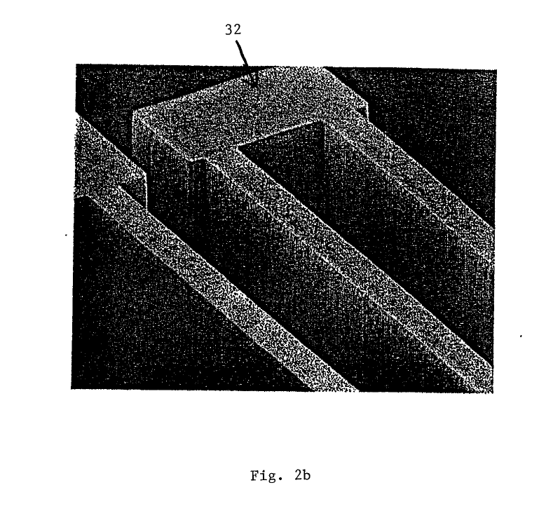

FIG. 2a shows a scanning electron microscope (SEM) image of a typical device showing the extremely large (700×700 μm²) mirror surface 30 and supporting springs 32. The entire mirror is suspended in space over the etched cavity 14 only supported at the two places where the serpentine springs 32 join the surrounding region.

FIG. 2b shows a close-up of the springs 32 themselves. Springs 32 comprise three elements parallel to the desired rotational axis which can twist without lowering into the cavity, so that the electrostatic energy produces a deflection of the mirror rather than merely pulling it down at both ends into the cavity. Springs of the present invention are typically 5-10 μm wide and 50 μm deep.

The direct current actuation of the devices was characterized with a Wyco optical profilometer. With no applied bias, even the largest plates were essentially flat, having a very slight upward deflection of 0.014° to the wafer surface. At higher bias voltages, the mirror plates deflected downwards into the cavity.

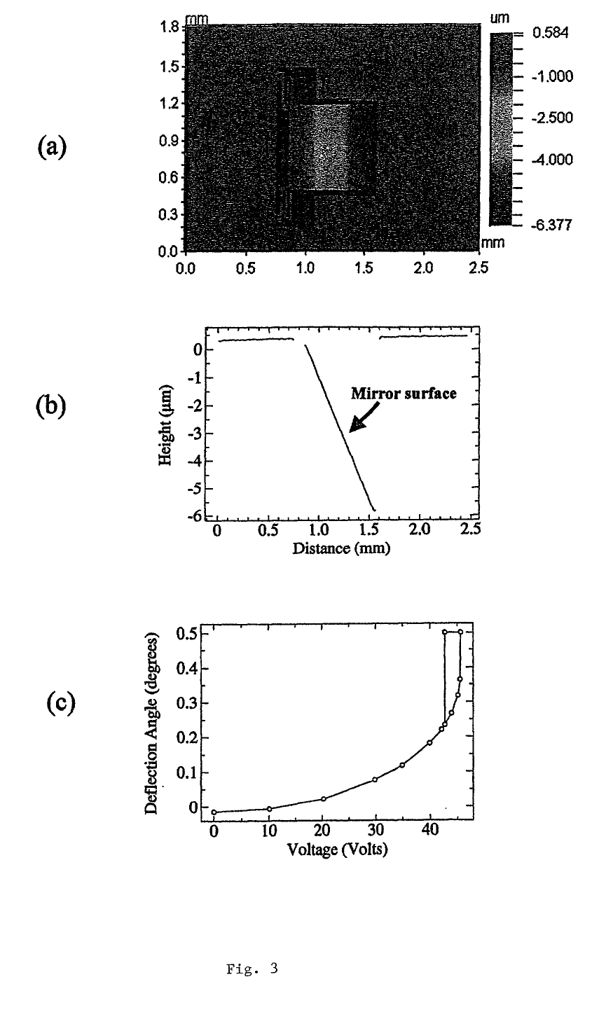

FIG. 3a illustrates the profilometer image of the device with an applied voltage of 55V. The grey scaly represents the depth of the mirror surface below the wafer surface. It is possible to obtain a depth profile along the mirror surface by extracting data from a region along the device's axis of symmetry. FIG. 3b illustrates a typical depth profile along the deflection plane, indicating a downward deflection of 6 μm at the end of the mirror plate, corresponding to an angle of 0.5° to the wafer surface. The mirror remains extremely flat (Why?) at all applied voltages, even in excess of 100V. The radius of curvature of of the mirrors of the present invention is 1 meter, or more, significantly greater than the current industry norm of 2 cm.

FIG. 3c is a chart illustrating deflection angle as a function of applied voltage for the same device. The data indicate a smooth increase of deflection angle with increasing voltage up to the pull in voltage of 46 volts. Then, as the voltage is decreased, the mirror remains down, due to the inverse square dependence of the electrostatic force with distance until the voltage falls below 42.7 V, at which point the mirror angle returns to the original deflection versus voltage curve, in this case falling to a value of 0.24°. Other devices show similar behavior, with pull in voltages ranging from 31 to 85 volts. (What is a “pull in voltage”?)

Measurement of reproducibility on all the devices revealed identical actuation of individual devices to the resolution of our measurement (<0.1V actuation voltage). Variations between different devices of the same type were limited to ≦2 V in terms of pull in voltage.

One of the desired characteristics of this device is that it should be able to reflect optical signals at angles between 0° and 0.6°. The data in FIG. 4 indicate a maximum deflection of 0.5°, which corresponds to a reflection angle of 1°. Thus the desired characteristic was exceeded by a large margin, with the target angle obtained at voltages of approximately 44V, several volts lower than the pull in voltage.

The resonance modes of the micro-mirror were calculated with the MEMCAD software suite. The lowest resonance mode, a “diving board” resonance is calculated to be 3 kHz. This frequency suggests that the device will operate below resonance with sub-millisecond switching times, which is acceptable for optical switching applications.

The micro-mirrors of the present invention are simpler and less expensive to fabricate than similar devices fabricated by conventional chemical vapor deposition of polycrystalline silicon, which require careful engineering to avoid stress-induced deformation. From a manufacturing standpoint, the method reproducibly produces large flat micro-mirrors in high yield.

While the invention has been described with respect to a preferred embodiment thereof, it will be appreciated by those of ordinary skill in the art that modifications can be made to the method and structure of the invention without departing from the spirit and scope thereof.

What is claimed is:

1. A method of forming a plurality of ultra-thin silicon micro-mechanisms that may be used as an actuator or mirror and having a thickness of 200 μm or less comprising the steps of:
a) providing a silicon substrate having a predetermined thickness and a contact surface;
b) etching a plurality of cavities in said silicon substrate through said contact surface;
c) providing an ultra-thin silicon wafer having a thickness of 200 μm or less;
d) providing an insulating layer on said silicon substrate and said silicon wafer;
f) locating said silicon substrate and said silicon wafer in a vacuum; bonding said silicon substrate and silicon wafer to one another in said vacuum;
g) forming a micro-mechanism including a resilient member proximate each of said cavities at a location for movement of a portion of said micro-mechanism into its respective cavity; and
h) forming a reflective coating on said moveable portion of each of said micro-mechanisms.

2. The method of claim 1 wherein said ultra-thin silicon wafer has a thickness of 100 μm or less.

3. The method of claim 1 wherein said ultra-thin silicon wafer has a thickness of 50 μm or less.

4. The method of claim 3 wherein said silicon substrate has a thickness of approximately 500 μm.

5. The method of claim 1 wherein said bonding of said silicon wafer to said silicon substrate is accomplished by the steps of:
a) placing said silicon wafer into contact with said silicon substrate along a portion of said silicon substrate that is proximate a line through a center portion of said silicon substrate; and then,
b) moving said silicon wafer into contact with said silicon substrate from said center portion outwardly along said silicon substrate into contact said silicon wafer.

6. The method of claim 5 including the step of placing said bonded silicon wafer and said silicon substrate into a heated environment to anneal said silicon wafer and said silicon substrate and increase the bond strength between said silicon wafer and said silicon substrate.

7. The method of claim 1 where said heated environment is at a temperature from 1050 degrees C. to 1100 degrees C.

8. The method of claim 1 wherein at least 1000 cavities are formed in said silicon substrate.

9. The method of claim 1 wherein said micro-mechanisms are formed by deep reaction ion etching.

10. The method of claim 1 wherein said silicon wafer is approximately 50 μm thick.

11. The method of claim 10 wherein said micro-mechanism is coated on a side of said silicon wafer facing away from said cavity first with chromium by vapor deposition and then said chromium is coated with gold by vapor deposition.

12. The method of claim 11 wherein said silicon dioxide is removed from said chromium/gold coated surface of said micro-mechanism prior to said vapor deposition.

13. The method of claim 12 wherein said chromium is coated to a thickness of approximately 50 angstroms and said gold is coated to a thickness of approximately 2000 angstroms.

14. The method of claim 1 wherein said insulating layer is a silicon dioxide layer approximately 1 μm thick.

15. The method of claim 14 wherein said silicon dioxide is removed from exposed surfaces of said silicon substrate and said silicon wafer after said micro-mechanism is formed.

16. The method of claim 14 wherein said silicon dioxide layer is provided by the process of wet oxidation.

17. The method of claim 1 wherein said insulating layer is chosen from the materials consisting of silicon oxide, silicon nitride and hafnium oxide.

18. The method of claim 1 wherein said movable portion is square with each side having a length of from 400 μm to 700 μm and the respective cavity for each of said movable portions is dimensionally slightly larger than said respective movable portion.

19. The method of claim 1 wherein said silicon wafer is formed from single crystal silicon.

20. The method of claim 19 wherein said silicon wafer is round having a diameter of from about 10 μm to about 10 mm.

21. The method of claim 1 wherein said resilient members are formed as beam torsion springs having a width of from 0.1 μm to 100 μm.

22. The method of claim 21 wherein said beam torsion springs have a thickness equal to the thickness of said silicon wafer.

23. The method of claim 22 wherein said beam torsion springs are chosen from the group consisting of single, double and triple beam torsion springs.

24. The method of claim 22 wherein said beam torsion springs have a width of from 5 μm to 10 μm.

25. The method of claim 24 wherein said beam torsion springs have an aspect ratio of 5:1 to 10:1 wherein the thickness of each of said beams is five (5) to ten (10) times greater than the width of the beam measured in the same area of the beam.

26. The method of claim 1 wherein said insulating coating is removed from said silicon wafer on the side of said silicon wafer facing away from said cavity.

27. The method of claim 26 wherein said removal of said insulating layer on said silicon wafer is done by the process of wet etching.

28. The method of claim 1 wherein each of said micro-mechanisms including said resilient member has a resonant frequency of three (3) kHz or greater.

29. The method of claim 1 wherein each of said micro-mechanisms including said resilient member and said respective cavity is configured for deflection of said movable portion into said cavity of up to 0.5 degrees.

30. The method of claim 30 wherein said reflective coating on said movable member is flat having a curvature equal to or greater than one (1) meter in any plane.

31. The method of claim 30 wherein said resilient member is configured for deflection of said reflective coating on said movable member a distance of 6 μm into said cavity.

32. The method of claim 1 wherein said bonding is fusion bonding.

33. The method of claim 1 further including the step of removing said insulating layer by wet etching.

34. The method of claim 15 wherein said insulating layer is removed by the process of wet etching.
